(19) United States
(12) Patent Application Publication
(10) Pub. No.: US 2002/0079578 A1
(43) Pub. Date: Jun. 27, 2002

(54) Semiconductor device having exposed adhesive sheet and method for manufacturing the same

(75) Inventor: Yoshihiro Matsuura, Tokyo (JP)

Correspondence Address: SUGHRUE, MION, ZINN, MACPEAK & SEAS, 2100 Pennsylvania Avenue, N.W., Washington, DC, 20037, US

(73) Assignee: NEC CORPORATION

(21) Appl. No.: 10/024,026

(22) Filed: Dec. 21, 2001

(30) Foreign Application Priority Data
Dec. 26, 2000 (JP) 2000-395345

(51) Int. Cl. H01L 23/48

(52) U.S. Cl. 257/738

(57) ABSTRACT

In a semiconductor device including an interposer substrate, a semiconductor chip, and an adhesive sheet for adhering the semiconductor chip to the interposer substrate, all outer periphery of the adhesive sheet is exposed to the outside.

### BACKGROUND OF THE INVENTION

1. Field of the Invention

The present invention relates to a semiconductor device such as a ball grid array (BGA)-type semiconductor device including an interposer substrate, a semiconductor chip and an adhesive sheet therebetween, and a method for manufacturing the same.

2. Description of the Related Art

Recently, semiconductor packages have been developed from quad flat packages (QFPs) to BGA-type packages to adopt chip size packages (CSPs) having substantially the same size as that of semiconductor chips.

A typical CSP is a BGA-type semiconductor package where a flip-chip type semiconductor chip is adhered face down via an adhesive sheet onto an interposer on which a printed wiring circuit and micro solder balls are formed. This will be explained later in detail.

In the prior art BGA-type semiconductor device, however, water and organic solvent cannot be released from the adhesive sheet to the outside, so that water vapor explosion may occur to cause a so-called popcorn phenomenon in a resin sealing layer. This decreases the manufacturing yield. Also, since the gap between the interposer substrate and the semiconductor chip is very long, it is difficult to completely inject resin for the sealing layer into the gap. As a result, voids are generated within the resin sealing layer, which deteriorates the reliability and life-time of the semiconductor device. Further, the contact area between the interposer substrate and the main portion of the resin sealing layer is increased, so that the resin sealing layer is warped by a reflowing process which warps the interposer substrate, and deteriorates the coplanarity of the printed wiring circuit thereof. This also will be explained later in detail.

### SUMMARY OF THE INVENTION

It is an object of the present invention to provide a semiconductor device capable of decreasing the manufacturing cost, improving the reliability and life-time, and suppressing the coplanirity of a printed wiring circuit.

Another object is to provide a method for manufacturing the above-mentioned semiconductor device.

According to the present invention, in a semiconductor device including an interposer substrate, a semiconductor chip, and an adhesive sheet for adhering the semiconductor chip to the interposer substrate, an outer periphery of the adhesive sheet is exposed to the outside.

Also, in a method for manufacturing a semiconductor device, an opening is perforated in an interposer substrate, and an opening is perforated in an adhesive sheet. Then, the interposer substrate is adhered to a first surface of the adhesive sheet so that the opening of the interposer substrate is in alignment with the opening of the adhesive sheet. Finally, a semiconductor chip is adhered to a second surface of the adhesive sheet.

Further, in a method for manufacturing a semiconductor device, an interposer substrate is adhered to a first surface of an adhesive sheet. Then, an opening is perforated in the interposer substrate and the adhesive sheet. Finally, a semiconductor chip is adhered to a second surface of the adhesive sheet.

### BRIEF DESCRIPTION OF THE DRAWINGS

The present invention will be more clearly understood from the description set forth below, as compared with the prior art, with reference to the accompanying drawings, wherein:

FIG. 1 is a cross-sectional view illustrating a prior art BGA-type semiconductor device;

FIGS. 2A and 2B are cross-sectional views for explaining the problems in the semiconductor device of FIG. 1;

FIGS. 3A through 3I are cross-sectional views for explaining a first embodiment of the method for manufacturing a BGA-type semiconductor device according to the present invention;

FIG. 4 is a perspective view of a first example of the interposer substrate and the adhesive sheet of FIG. 3I;

FIGS. 5A and 5B are perspective views of the device of FIGS. 3C and 3D, respectively, when the first example of FIG. 4 is adopted;

FIG. 6 is a perspective view of a second example of the interposer substrate and the adhesive sheet of FIG. 3I;

FIGS. 7A and 7B are perspective views of the device of FIGS. 3C and 3D, respectively, when the second example of FIG. 6 is adopted;

FIG. 8 is a perspective view of a third example of the interposer substrate and the adhesive sheet of FIG. 3I;

FIGS. 9A and 9B are perspective views of the device of FIGS. 3C and 3D, respectively, when the third example of FIG. 4 is adopted;

FIG. 10 is a perspective view of a fourth example of the interposer substrate and the adhesive sheet of FIG. 3I;

FIGS. 11A and 11B are perspective views of the device of FIGS. 3C and 3D, respectively, when the fourth example of FIG. 10 is adopted;

FIGS. 12A through 12D are cross-sectional views for explaining a second embodiment of the method for manufacturing a BGA-type semiconductor device according to the present invention; and

FIG. 13 is a table showing the effect of the embodiments according to the present invention as compared with the prior art.

### DESCRIPTION OF THE PREFERRED EMBODIMENTS

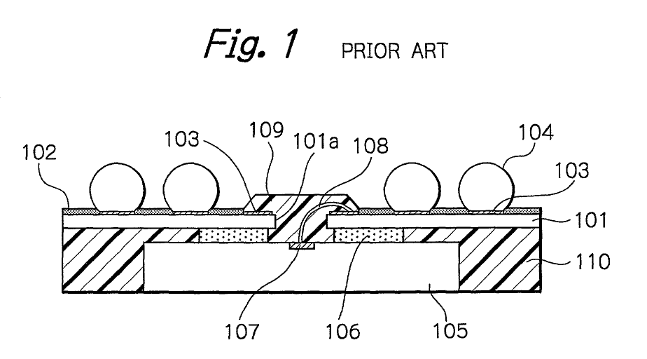

Before the description of the preferred embodiments, a prior art BGA-type semiconductor device will be explained with reference to FIG. 1 manufactured by a board-on-chip (BOC) process or a chip-on-board (COB) process.

In FIG. 1, reference numeral 101 designates an interposer substrate having a front surface on which a wiring layer (not shown) and a solder resist pattern 102 thereon are formed. The interposer substrate 101 is made of polyimide, glass epoxy, ceramic or aromatic polyamide fiber (aramid) including resin. Also, formed in the openings of the solder resist pattern 102 is an electroplating terminal layer 103 made of nickel, gold or the like to form a printed wiring circuit. Further, micro solder balls 104 are provided on the electroplating terminal layer 103.

A semiconductor chip 105 is mounted by an adhesive sheet 106 on a back surface of the interposer substrate 101. In this case, the semiconductor chip 105 is adhered face down onto the interposer substrate 101, so that pads 107 of the semiconductor chip 105 are located within an opening 101a of the interposer substrate 101. Note that the adhesive sheet 106 is preferably made of material to reduce thermal stress caused by the difference in thermal expansion coefficient between the interposer substrate 101 and the semiconductor chip 105.

Wires 108 are connected between the pads 107 and the respective terminals of the electroplating terminal layer 103.

A sealing layer 109 made of epoxy resin is provided within the opening 101a of the interposer substrate 101, in order to protect the pads 107. On the other hand, a sealing layer 110 made of epoxy resin is provided in a gap between the interposer substrate 101 and the semiconductor chip 105, so that the periphery thereof is sealed by the sealing layer 110.

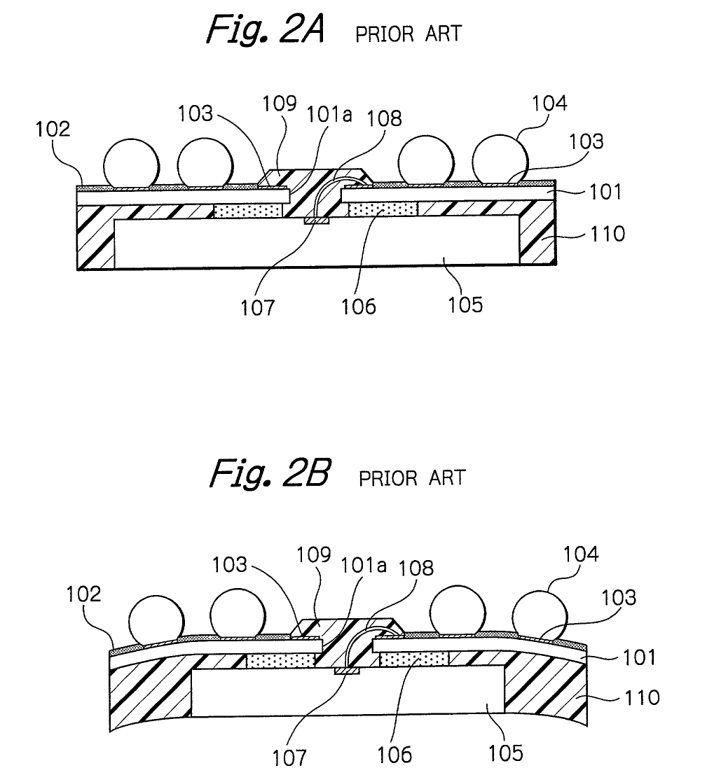

As illustrated in FIG. 2A, if the semiconductor chip 106 is relatively large in size, for example, 10 mm×17 mm, when a reflowing process is performed upon the sealing layers 109 and 110, water and organic solvent cannot be released from the adhesive sheet 106 to the outside, so that water vapor explosion may occur to cause a so-called popcorn phenomenon in the sealing layer 110. This decreases the manufacturing yield. Also, since the gap between the interposer substrate 101 and the semiconductor chip 105 is very long, it is difficult to completely inject resin for the sealing layer 110 into the gap due to the relationship between the resin injecting speed and the viscosity of resin. As a result, voids are generated within the sealing layer 110, which deteriorates the reliability and life-time of the semiconductor device.

On the other hand, as illustrated in FIG. 2B, if the semiconductor chip 106 is relatively small in size, for example, 6 mm×10 mm, the contact area between the interposer substrate 101 and the main portion of the sealing layer 110 is increased, so that the sealing layer 110 is warped by the reflowing process to warp the interposer substrate 101, which deteriorates the coplanarity of the printed wiring circuit thereof. In order to suppress the warpage of the sealing layer 110, the thermal expansion coefficient of the interposer substrate 101 has to be close to that of the semiconductor chip 105; in this case, however, the manufacturing cost is increased, and the selection of material for the interposer substrate 101 is limited in view of the viscosity of resin of the sealing layer 110 and the affinity of the interposer substrate 101 to the semiconductor chip 106. Also, if the semiconductor chip 106 is large in size, when a large unbalance is present between the longitudinal directional size and the traverse directional size thereof, the coplanarity of the printed wiring circuit is also deteriorated.

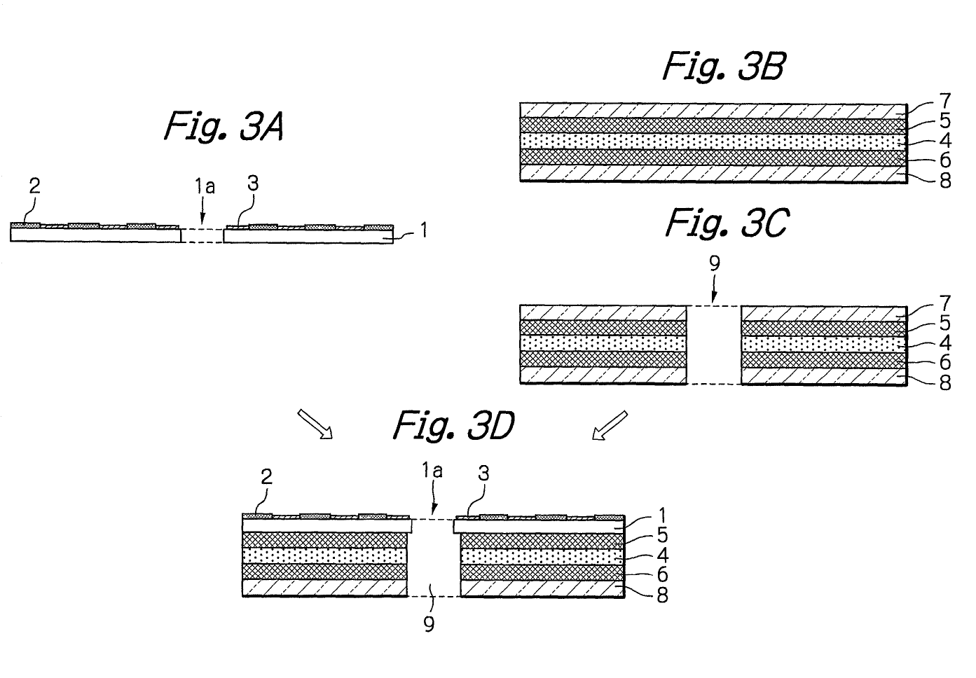

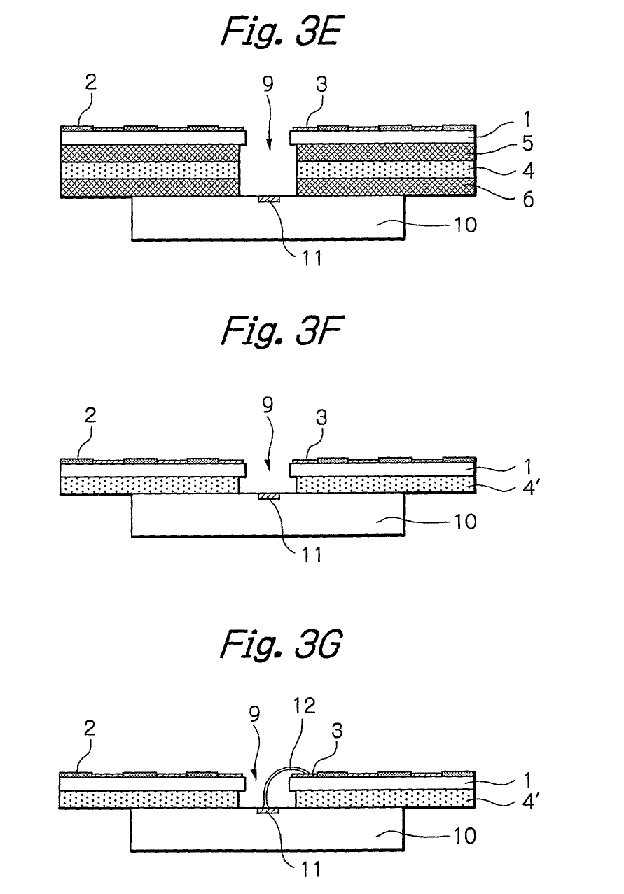

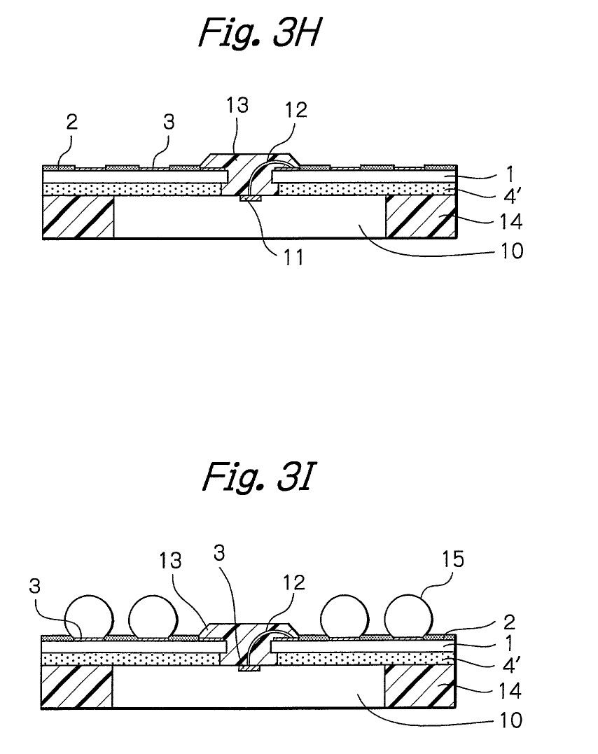

A first embodiment of the method for manufacturing a BGA-type semiconductor device according to the present invention will be explained next with reference to FIGS. 3A through 3I.

First, referring to FIG. 3A, an about 0.1 to 0.2 mm thick interposer substrate 1 made of glass epoxy, polyimide, ceramic or aramid including resin is prepared. Then, a wiring layer (not shown) is formed by an etching process or an additive process on a front surface of the interposer substrate 1, and a solder resist pattern 2 is formed thereon for an electrical isolation. Then, an electroplating process using nickel, gold or the like is carried out to form terminals 3 of a printed wiring circuit. Then, an opening 1a is perforated in the interposer substrate 1 by a pressing process using metal molds. Generally, note that one interposer substrate is prepared for a plurality of semiconductor chips, and the interposer substrate is divided into pieces each for one of the semiconductor chips.

On the other hand, referring to FIG. 3B, surfaces of a polyimide sheet 4 are coated by thermoplastic adhesive layers 5 and 6, respectively, which are protected by poly thylene terephathalate (PET) films 7 and 8, respectively.

Next, referring to FIG. 3C, an opening 9 is perforated in the polyimide sheet 4, the thermoplastic adhesive layers 5 and 6, and the PET films 7 and 8 by a pressing process using metal molds.

Next, referring to FIG. 3D, the PET film 7 is peeled off. Then, the back surface of the interposer substrate 1 is provisionally adhered to the adhesive layer 5 at a temperature of about 40° C. to 100° C. Then, after the relationship in location between the interposer substrate 1 and the polyimide sheet 4 is adjusted, the back surface of the interposer substrate 1 is surely adhered to the adhesive layer 5 at a temperature of about 60° C. to 120° C.

Next, referring to FIG. 3E, the PET film 8 is peeled off. Then, a semiconductor chip 10 having pads 11 is adhered to the adhesive layer 6 at a temperature of about 90° C. to 150° C. at a pressure of about 5 to 15 kg/cm² for about 1 to 2 seconds. As a result, the pads 11 are located within the opening 9 of the polyimide sheet 4.

Next, a heating process is performed upon the adhesive layers 5 and 6 without applying a pressure to the semiconductor chip 10 at a temperature of about 100° C. to 170° C. for about one hour, and thereafter, a baking process is performed upon the adhesive layers 5 and 6 without applying a pressure to the semiconductor chip 10 at a temperature of about 170° C. for about two hours. As a result, as illustrated in FIG. 3F, the adhesive layers 5 and 6 are combined with the polyimide sheet 4 to form an adhesive sheet 4′. In this case, organic solvent included in the adhesive layers 205 and 206 would be adhered to the surfaces of the interposer substrate 1, the semiconductor chip 10 and the pads 11. Therefore, in order to remove such organic solvent, a plasma cleaning process using a mixture of Ar gas and ozone gas is carried out.

Next, referring to FIG. 3G, a wire bonding process is carried out, so that the pads 11 are electrically connected to the respective ones of the terminals 3 by 30 μm-diameter wires 12 made of Au. Then, a plasma cleaning process using a mixture of Ar gas and ozone gas is carried out.

Next, referring to FIG. 3H, resin is injected by a transfer sealing process into the opening (cavity) 9 of the adhesive sheet 4′, so that the pads 11 and the wires 13 are covered by a resin sealing layer 13. Also, resin is injected by a transfer sealing process into the periphery of the semiconductor chip 10. Then, a baking process is carried out at a temperature of about 170° C. to 180° C. for about 4 to 6 hours, so as to bake the resin sealing layers 13 and 14.

Finally, referring to FIG. 3I, micro solder balls 15 are mounted on the terminals 3, and a reflowing process is performed thereupon, so that the micro solder balls 15 are melted and adhered to the terminals 3. Then, a cleaning process is carried out, and after that, a dicing process is carried out, so that a plurality of semiconductor packages are obtained.

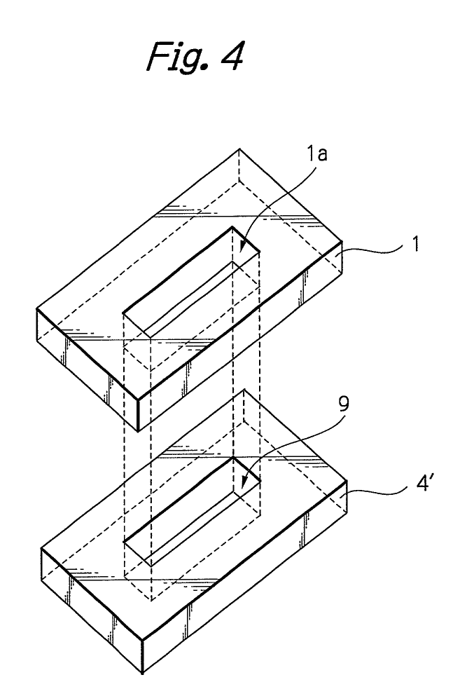

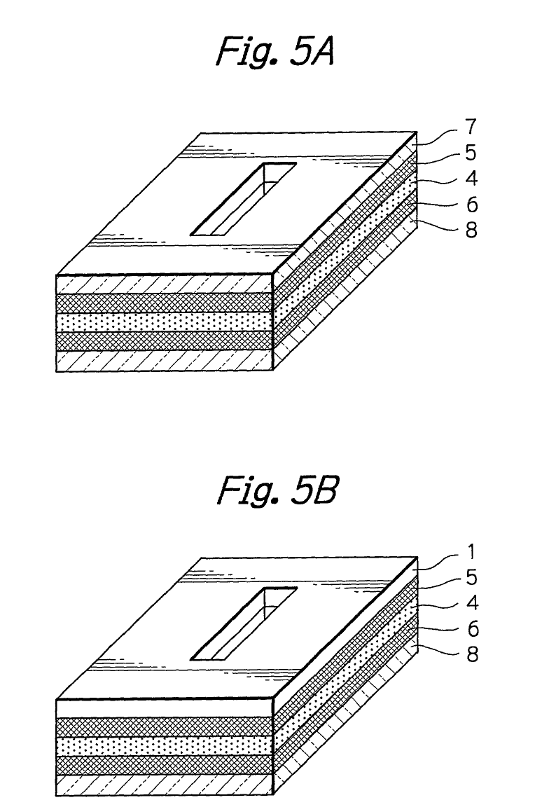

A first example of the semiconductor device obtained by the method as illustrated in FIGS. 3A through 3I is explained next with reference to FIGS. 4, 5A and 5B.

As illustrated in FIG. 4, which is a perspective view of the interposer substrate 1 and the adhesive sheet 4′ of FIG. 3I, since the opening 1a of the interposer substrate 1 and the opening 9 of the adhesive sheet 4′ can be perforated by the same metal molds, the shape of the interposer substrate 1 can be the same as that of the adhesive sheet 4′. In this case, note that a perspective view of the device of FIG. 3C is illustrated in FIG. 5A, and a perspective view of the device as illustrated in FIG. 3D is illustrated in FIG. 5B.

Thus, in the first example of FIGS. 4, 5A and 5B, since the outer periphery of the adhesive sheet 4′ is exposed to the outside, the resin sealing layer 14 is not in contact with the interposer substrate 1, i.e., the resin sealing layer 14 is in contact with only the adhesive sheet 4′ and the semiconductor 10.

Therefore, if the semiconductor chip 10 is relatively large in size, when a reflowing process is performed upon the resin sealing layers 13 and 14, water and organic solvent can be easily released from the adhesive sheet 4′ to the outside, so that water vapor explosion hardly occurs to prevent a so-called popcorn phenomenon in the sealing layer 14. Also, since there is no gap between the interposer substrate 1 and the semiconductor chip 10, resin for the sealing layer 14 can be easily injected, so that no voids are generated within the sealing layer 14. Further, if the semiconductor chip 10 is relatively small in size, since the interposer substrate 1 and the sealing layer 14 are entirely coupled by the interposition of the adhesive sheet 4′, the sealing layer 14 is never warped by the reflowing process.

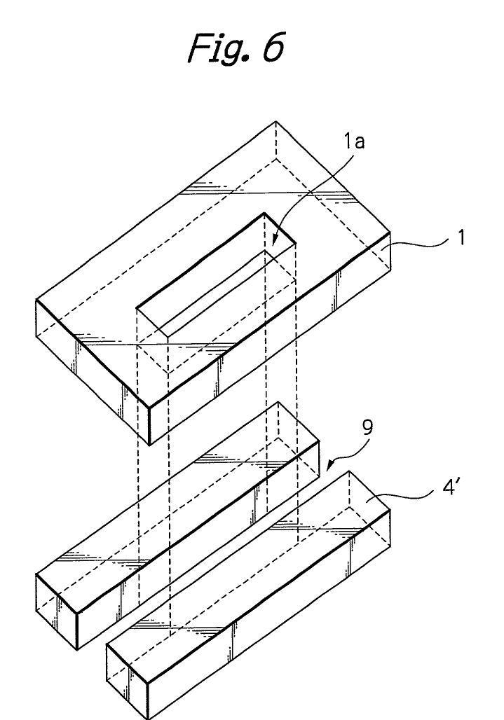

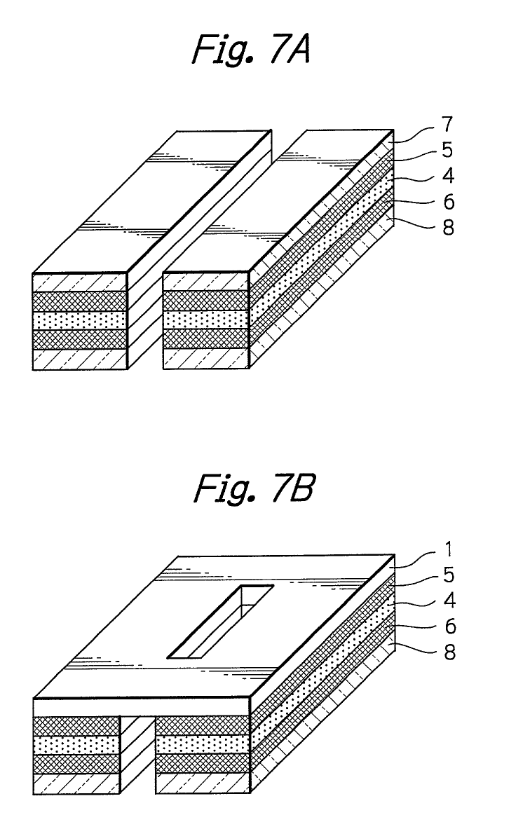

A second example of the semiconductor device obtained by the method as illustrated in FIGS. 3A through 3I is explained next with reference to FIGS. 6, 7A and 7B.

As illustrated in FIG. 6, which is a perspective view of the interposer substrate 1 and the adhesive sheet 4′ of FIG. 3I, the opening 1a of the interposer substrate 1 can be perforated by first rectangular metal molds, and the opening 9 of the adhesive sheet 4′ can be perforated by second rectangular metal molds having the same width as the first rectangular metal molds. Therefore, the shape of the interposer substrate 1 is approximately the same as that of the adhesive sheet 4′. In this case, note that a perspective view of the device of FIG. 3C is illustrated in FIG. 7A, and a perspective view of the device as illustrated in FIG. 3D is illustrated in FIG. 7B.

Thus, in the second example of FIGS. 6, 7A and 7B, since the outer periphery of the adhesive sheet 4′ is also exposed to the outside, only a part of the resin sealing layer 14 is in contact with the interposer substrate 1, i.e., the resin sealing layer 14 is almost in contact with only the adhesive sheet 4′ and the semiconductor 10.

Therefore, if the semiconductor chip 10 is relatively large in size, when a reflowing process is performed upon the resin sealing layers 13 and 14, water and organic solvent can be easily released from the adhesive sheet 4′ to the outside, so that water vapor explosion hardly occur to prevent a so-called popcorn phenomenon in the sealing layer 14. Also, since there is little gap between the interposer substrate 1 and the semiconductor chip 10, resin for the sealing layer 14 can be easily injected, so that voids are hardly generated within the sealing layer 14. Further, if the semiconductor chip 10 is relatively small in size, since the interposer substrate 1 and the sealing layer 14 are almost entirely coupled by the interposition of the adhesive sheet 4′, the sealing layer 14 is hardly warped by the reflowing process.

In the second example as illustrated in FIGS. 6, 7A and 7B, an alignment of the interposer substrate 1 to the polyimide sheet 4 as illustrated in FIG. 3D can be simplified as compared with the first example as illustrated in FIGS. 4, 5A and 5B.

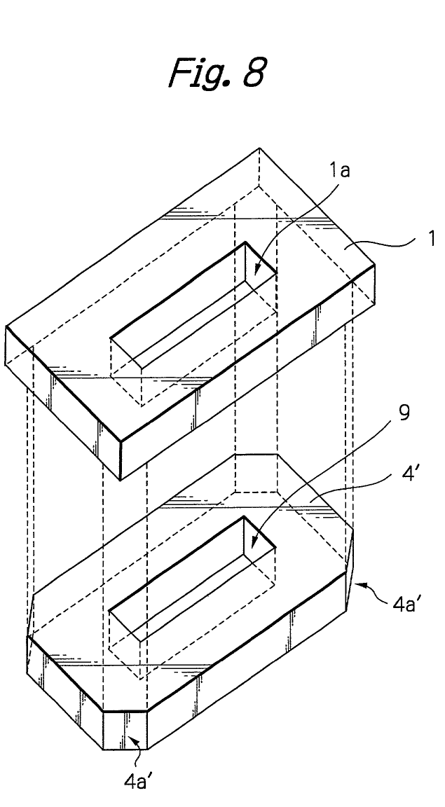

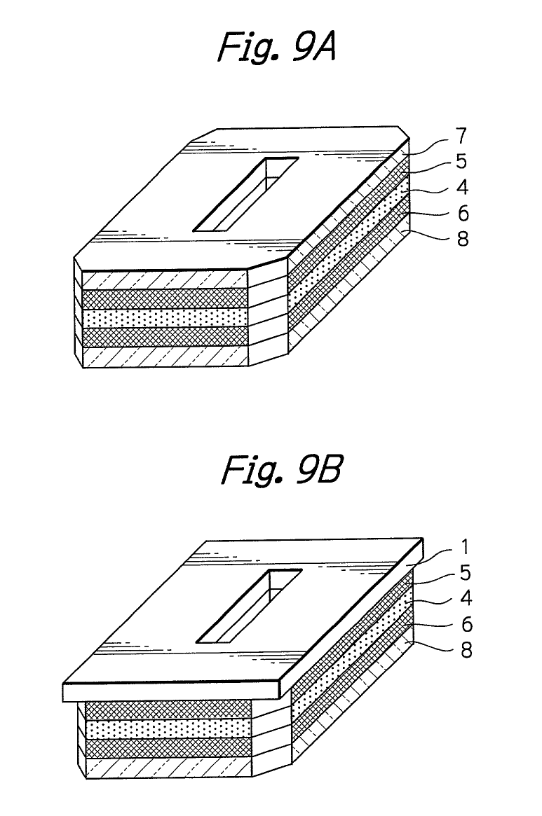

A third example of the semiconductor device obtained by the method as illustrated in FIGS. 3A through 3I is explained next with reference to FIGS. 8, 9A and 9B.

As illustrated in FIG. 8, which is a perspective view of the interposer substrate 1 and the adhesive sheet 4′ of FIG. 3I, the opening 1a of the interposer substrate 1 can be perforated by first rectangular metal molds, and the opening 9 of the adhesive sheet 4′ can be perforated by second rectangular metal molds including small rectangular metal molds as well as the first rectangular metal molds. That is, the small rectangular metal molds are used for forming four bevel portions 4′a for one contour of the adhesive sheet 4′ for one semiconductor chip 10. Therefore, the shape of the interposer substrate 1 is approximately the same as that of the adhesive sheet 4′. In this case, note that a perspective view of the device of FIG. 3C is illustrated in FIG. 9A, and a perspective view of the device as illustrated in FIG. 3D is illustrated in FIG. 9B.

Thus, in the third example of FIGS. 8, 9A and 9B, since the outer periphery of the adhesive sheet 4′ is also exposed to the outside, only a part of the resin sealing layer 14 is in contact with the interposer substrate 1, i.e., the resin sealing layer 14 is almost in contact with only the adhesive sheet 4′ and the semiconductor 10.

Therefore, if the semiconductor chip 10 is relatively large in size, when a reflowing process is performed upon the resin sealing layers 13 and 14, water and organic solvent can be easily released from the adhesive sheet 4′ to the outside, so that water vapor explosion hardly occurs to prevent a so-called popcorn phenomenon in the sealing layer 14. Also, since there is little gap between the interposer substrate 1 and the semiconductor chip 10, resin for the sealing layer 14 can be easily injected, so that voids are hardly generated within the sealing layer 14. Further, if the semiconductor chip 10 is relatively small in size, since the interposer substrate 1 and the sealing layer 14 are almost entirely coupled by the interposition of the adhesive sheet 4′, the sealing layer 14 is hardly warped by the reflowing process.

In the third example as illustrated in FIGS. 8, 9A and 9B, since the resin sealing layer 14 instead of the adhesive sheet 4′ is provided at the four edges of the adhesive sheet 4′ for every semiconductor chip, when a dicing process is carried out to obtain a plurality of semiconductor packages, residue of adhesive material can be reduced.

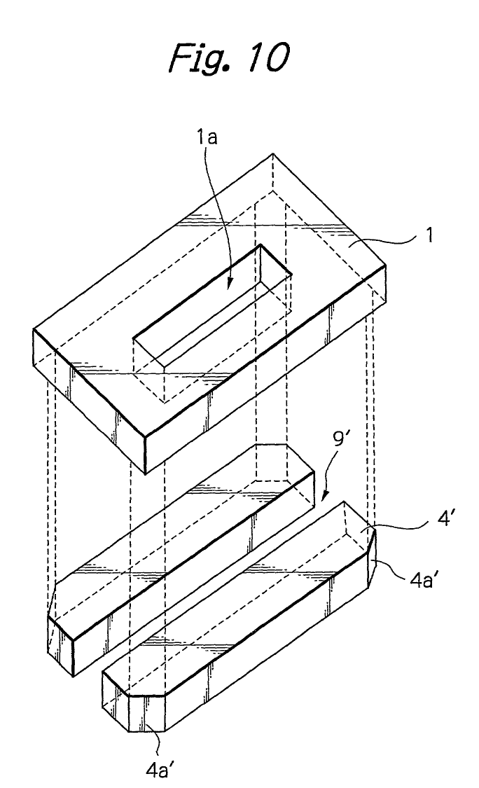

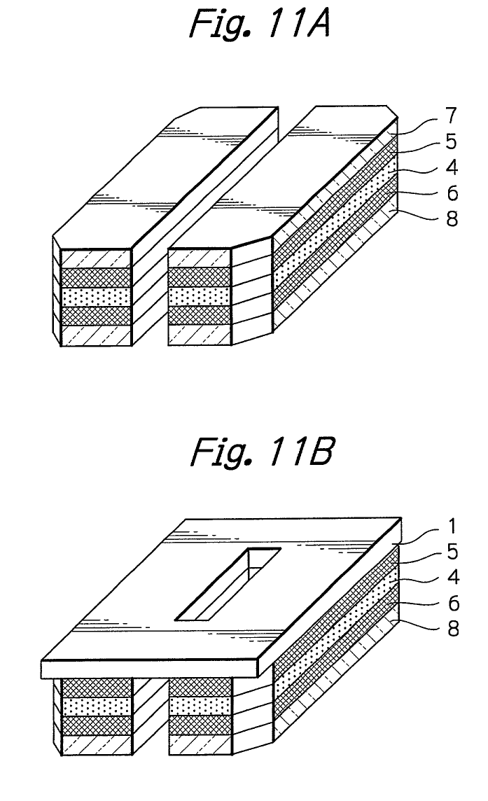

A fourth example of the semiconductor device obtained by the method as illustrated in FIGS. 3A through 3I is explained next with reference to FIGS. 10, 11A and 11B.

As illustrated in FIG. 10, which is a perspective view of the interposer substrate 1 and the adhesive sheet 4′ of FIG. 3I, the opening 1a of the interposer substrate 1 can be perforated by first rectangular metal molds, and the opening 9 of the adhesive sheet 4′ can be perforated by second rectangular metal molds including small rectangular metal molds as well as metal molds having the same width as the first rectangular metal molds. That is, the second example as illustrated in FIG. 6 and the third example as illustrated in FIG. 8 are combined to form the fourth example as illustrated in FIG. 10. Therefore, the shape of the interposer substrate 1 is approximately the same as that of the adhesive sheet 4′. In this case, note that a perspective view of the device of FIG. 3C is illustrated in FIG. 11A, and a perspective view of the device as illustrated in FIG. 3D is illustrated in FIG. 11B.

In the fourth example as illustrated in FIGS. 10, 11A and 11B, an alignment of the interposer substrate 1 to the polyamide sheet 4 as illustrated in FIG. 3D can be simplified as compared with the first; example as illustrated in FIGS. 4, 5A and 5B. Additionally, since the resin sealing layer 14 instead of the adhesive sheet 4′ is provided at the four edges of the adhesive sheet 4′ for every semiconductor chip, when a dicing process is carried out to obtain a plurality of semiconductor packages, residue of adhesive material can be reduced.

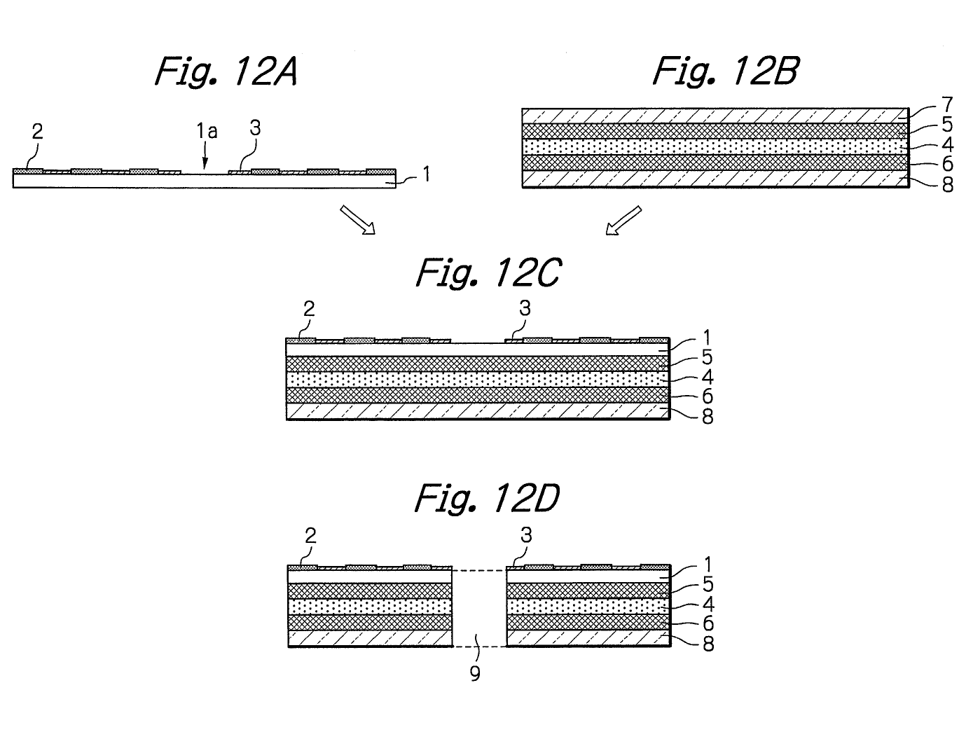

A second embodiment of the method for manufacturing a BGA-type semiconductor device according to the present invention will be explained next with reference to FIGS. 12A through 12D as well as FIGS. 3E through 3I.

First, referring to FIG. 12A, an about 0.1 to 0.2 mm thick interposer substrate 1 made of glass epoxy, polyimide, ceramic or aramid including resin is prepared. Then, a wiring layer (not shown) is formed by an etching process or an additive process on a front surface of the interposer substrate 1, and a solder resist pattern 2 is formed thereon for an electrical isolation. Then, an electroplating process using nickel, gold or the like is carried out to form terminals 3 of a printed wiring circuit. Generally, note that one interposer substrate is prepared for a plurality of semiconductor chips, and the interposer substrate is divided into pieces each for one of the semiconductor chips.

On the other hand, referring to FIG. 12B, surfaces of a polyimide sheet 4 made are coated by thermoplastic adhesive layers 5 and 6, respectively, which are protected by PET films 7 and 8, respectively.

Next, referring to FIG. 12C, the PET film 7 is peeled off. Then, the back surface of the interposer substrate 1 is provisionally adhered to the adhesive layer 5 at a temperature of about 40° C. to 100° C. Then, the back surface of the interposer substrate 1 is surely adhered to the adhesive layer 5 at a temperature of about 60° C. to 120° C.

Next, referring to FIG. 12D, an opening 9 is perforated in the interposer substrate 1, the polyimide sheet 4, the thermoplastic adhesive layers 5 and 6, and the PET films 7 and 8 by a pressing process using metal molds.

Thereafter, the same steps as illustrated in FIGS. 3E, 3F, 3G, 3H and 3I are carried out to obtain the same semiconductor device as illustrted in FIG. 3I. In this case, an example of the semiconductor device obtained by the method as illustrated in FIGS. 12A, 12B, 12C and 12D as well as FIGS. 3E, 3F, 3G, 3H and 3I is illustrted in FIGS. 4, 5A and 5B.

In the method as illustrted in FIGS. 12A, 12B, 12C and 12D as well as FIGS. 3E, 3F, 3G, 3H and 3I, only one pressing process is carried out, which would decrease the manufacturing cost. Additionally, an alignment between the interposer substrate and the adhesive sheet 4′ (the polyimide sheet 4) is unnecessary, which also would decrease the manufacturing cost.

In the above-described manufacturing methods, either or both of the PET films 7 and 8 can be omitted.

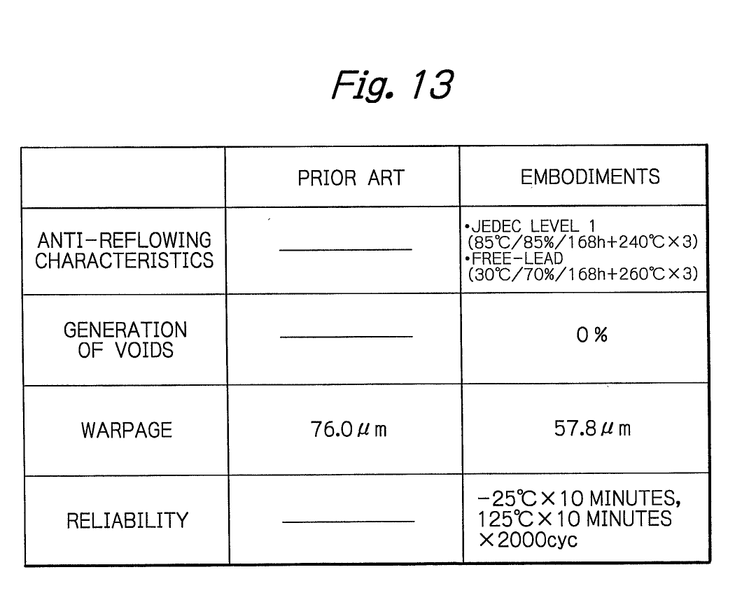

The results of comparison of prior art semiconductor device and semiconductor devices obtained by the above-described embodiments executed by the inventor are shown in FIG. 13. The semiconductor devices according to the embodiments passed a Joint Electron Device Engineering Council (JEDEC) Level 1 where the atmosphere is heated at 85° C. with a humidity of 85 percent for 168 hours and then, reflowing processes are carried out three times at 240° C. Also, there were no noids in the semiconductor devices according to the embodiments. Further, the prior art semiconductor devices have a package size of 17 mm×10 mm was 76.0 μm, while the semiconductor devices have a package size of 17 mm×10 mm according to the embodiments was 57.8 μm. Additionally, the semiconductor devices having a package size of 15 mm×8 mm according to the embodiments passed 2000 cycles of a mounting reliability test are carried out at a temperature of −25° C. for 10 minutes and a temperature of 125° C. for 10 minutes.

As explained hereinabove, according to the present invention, since water and organic solvent can be easily released from the adhesive sheet to the outside, so that water vapor explosion hardly occurs to prevent a so-called popcorn phenomenon in the sealing layer, the manufacturing cost can be decreased. Also, since there is no gap or little gap between the interposer substrate and the semiconductor chip so that no voids are generated within the sealing layer, the reliability and life-time of the semiconductor device can be improved. Further, since the interposer substrate and the sealing layer are entirely coupled by the interposition of the adhesive sheet, the sealing layer is never warped by a reflowing process, thus suppressing the deterioration of the coplanirity of the printed wiring circuit.

1. A semiconductor device comprising:
an interposer substrate;
a semiconductor chip; and
an adhesive sheet, provided between said interposer substrate and said semiconductor chip, for adhering said semiconductor chip to said interposer substrate,
an outer periphery of said adhesive sheet being exposed to the outside.

2. The device as set forth in claim 1, wherein the outer periphery of said adhesive sheet exposed to the outside is continuous around the periphery of said interposer substrate.

3. The device as set forth in claim 1, wherein said adhesive sheet has a similar size to that of said interposer substrate.

4. The device as set forth in claim 1, wherein said adhesive sheet comprises two parallel portions.

5. The device as set forth in claim 3, wherein said adhesive sheet has four bevel portions at its edges.

6. The device as set forth in claim 4, wherein each of said parallel portions has two bevel portions at its edges.

7. The device as set forth in claim 1, wherein said adhesive sheet comprises:
a thermally stable polymer sheet; and
two adhesive layers formed on both surfaces of said thermally stable polymer sheet.

8. The advice as set forth in claim 7, wherein said thermally stable polymer sheet comprises a polyimide sheet.

9. The device as set forth in claim 1, wherein said interposer substrate comprises one of glass epoxy, polyimide, ceramic and aramid including resin.

10. The device as set forth in claim 1, being a ball grid array-type semiconductor device.

11. A semiconductor device comprising:
an interposer substrate;
a semiconductor chip;
an adhesive sheet, provided between said interposer substrate and said semiconductor chip, for adhering said semiconductor chip to said interposer substrate, an outer periphery of said adhesive sheet being exposed to the outside;
a resin sealing layer surrounding a periphery of said semiconductor chip and formed on said adhesive sheet.

12. The device as set forth in claim 11, wherein a part of said resin sealing layer is in direct contact with said interposer substrate.

13. The device as set forth in claim 11, wherein said adhesive sheet comprises two parallel portions,
said resin sealing layer being in direct contact with said interposer substrte through a gap between said parallel portions.

14. The device as set forth in claim 11, wherein said adhesive sheet comprises bevel portions,
said resin sealing layer being in direct contact with said interposer substrte through said bevel portions.

15. A method for manufacturing a semiconductor device, comprising the steps of:
perforating an opening in an interposer substrate;
perforating an opening in an adhesive sheet;
adhering said interposer substrate to a first surface of said adhesive sheet so that the opening of said interposer substrate is in alignment with the opening of said adhesive sheet; and
adhering a semiconductor chip to a second surface of said adhesive sheet.

16. The method as set forth in claim 15, wherein said adhesive sheet perforating step perforates said adhesive sheet so that two parallel portions are formed in said adhesive sheet.

17. The method as set forth in claim 15, wherein said adhesive sheet perforating step perforates said adhesive sheet so that four bevel portions are formed at edges of said adhesive sheet.

18. The method as set forth in claim 16, wherein said adhesive sheet perforating step perforates said adhesive sheet so that each of said parallel portions has two bevel portions at edges thereof.

19. A method for manufacturing a semiconductor device, comprising the steps of:
adhering an interposer substrate to a first surface of a adhesive sheet:
perforating an opening in said interposer substrate and said adhesive sheet; and
adhering a semiconductor chip to a second surface of said adhesive sheet.
